(19) United States
(12) Patent Application Publication
(10) Pub. No.: US 2012/0070576 A1
(43) Pub. Date: Mar. 22, 2012

(54) COATED POROUS METAL MEDIUM

(75) Inventors: Roland Groenen, Gent (BE); Kris Van Hege, Gent (BE)

(73) Assignee: NV BEKAERT SA

(21) Appl. No.: 13/306,191

(22) Filed: Nov. 29, 2011

Related U.S. Application Data
(62) Division of application No. 12/089,434, filed on Apr. 7, 2008.

(30) Foreign Application Priority Data
Oct. 11, 2005 (EP) 05109411.8

(51) Int. Cl. C23C 16/44; C23C 16/34; C23C 16/30; C23C 16/40

(52) U.S. Cl. 427/244

(57) ABSTRACT

The invention relates to a coated porous medium comprising metal particles. The metal particles define a free area surface S. The free area surface S is substantially completely coated with a coating layer. The coating layer is substantially conformal, substantially uniform in composition and has substantially the same thickness over the whole free area surface. The invention further relates to the use of a coated medium as filter medium and to a method of manufacturing a coated medium.

### FIELD OF THE INVENTION

The invention relates to a coated porous metal medium and to the use of such a coated medium as filter medium.

The invention further relates to a method of manufacturing a coated medium.

### BACKGROUND OF THE INVENTION

Porous metal media comprising sintered metal fibers and/or sintered metal powder are well known in the art. They are for example used as filter media.

The in-depth coating of a porous metal medium may offer the medium many attractive properties such as corrosion resistance, chemical resistance, high temperature resistance, . . .

However, it is hard to obtain a uniform and conformal coating throughout the thickness of the medium.

Many coating techniques have been tested without success. Most coating techniques do not allow to obtain a uniform and conformal coating throughout the thickness of the medium, for example because the outer pores of the medium are sealed before the interior can be coated.

By means of activated chemical vapour deposition such as hot filament the in-depth coating of a porous medium is not satisfactory.

In hot filament chemical vapour deposition for example, the process is generally so reactive that the precursor will react and will be deposited at the outer surface of the porous medium so that the interior of the medium will not be coated.

The in-depth coating of a porous metal medium by thermal CVD is a complex process and does not allow to coat the medium in-depth with a conformal coating layer that has a uniform composition and a constant coating thickness over the thickness of the medium.

### SUMMARY OF THE INVENTION

It is an object of the present invention to provide a coated porous metal medium avoiding the problems of the prior art.

It is another object of the present invention to provide a coated porous metal medium whereby the whole free area surface S is coated.

It is a further object of the invention to provide a coated porous metal medium whereby the coating is conformal and uniform over the whole free area surface.

It is a further object of the present invention to provide a coated porous metal medium whereby the whole free area surface S of the medium is coated with a closed coating having a minimal thickness.

According to a first aspect of the present invention a coated porous medium comprising metal particles is provided.

The metal particles of the medium define a free area surface S, i.e. the total surface of the medium that is in contact or may have contact with air or another gas or that is in contact with the fluid to be filtered in case the medium is used for filtration.

The free area surface S includes thus not only the free area surface S at the outer surface of the medium, but also the free area surface S in the pores of the medium.

According to the present invention, the free area surface S of the metal surface is substantially completely coated with a coating layer. The coating layer is substantially conformal over the whole free area surface S; the coating layer is substantially uniform in composition over the whole free area surface S and has substantially the same thickness over the whole free area surface.

Porous Metal Medium

The metal particles of the porous metal medium comprise preferably steel such as stainless steel. Preferred alloys comprise 316 L, FeCrAlloy®, Alloy HR or Aluchrome®.

The metal particles of the porous metal medium preferably comprise metal powder or metal fibers or a combination of metal powder and metal fibers.

The metal fibers have preferably a diameter ranging between 1 μm and 100 μm. More preferably, the diameter of the metal fibers is between 1 and 35 μm, for example 2 μm, 4 μm, 8 μm or 12 μm.

The metal fibers may be obtained by any technique known in the art. They are for example obtained by bundle drawing or shaving.

The porous metal medium may comprise a woven or a non-woven porous metal medium.

In a preferred embodiment the porous metal medium comprises a non-woven porous metal medium comprising sintered metal fibers.

In an alternative embodiment the porous metal medium comprises sintered metal powder.

In a further embodiment the porous metal medium comprises a combination of metal fibers and metal powder particles which have been sintered.

Coating Layer

The coating layer is preferably applied by atomic layer deposition (ALD).

ALD is a coating technique based on Chemical Vapor Deposition (CVD). In ALD a coating is applied by alternating exposures of the surface of two or more chemical reactants.

The ALD technique offers many advantages. ALD allows for example to obtain uniform, ultra thin coatings. Furthermore, the thickness of the coating can be precisely controlled on the atomic scale.

When ALD is used to apply a coating on a porous metal medium according to the present invention, a coated porous metal medium having unique characteristics is obtained.

First of all, as ALD allows to infiltrate into the pores of a complex medium such as a porous metal medium comprising metal fibers, the free area surface S is substantially completely coated with the coating layer. This means that the free area surface S is coated over the whole thickness of the medium.

With “substantially completely” is meant that although there may be some accidental uncoated spots there are no structural uncoated areas.

All the porous media according to the present invention showed that at least 95% of the total free area surface S was coated.

For most embodiments more than 99% of the total free area surface S was coated.

A second characteristic of the coating layer according to the present invention is that the coating is conformal.

With a conformal coating is meant a coating that is conserving the shape of the non-coated porous medium. A conformal coating is thus exactly or almost exactly replicating the shape of the surface of the non-coated porous medium.

With “substantially conformal” is meant that although there may be some small, accidental deviations over the surface and over the thickness of the medium, there are no structural deviations, neither over the surface of the medium, nor over the thickness of the medium.

A third characteristic of a coating layer according to the present invention is that the coating layer has a substantially uniform composition over the whole free area surface.

With “a substantially uniform composition” is meant that although there may be some small, accidental deviations in composition over the surface and over the thickness of the medium, there are no structural deviations neither over the surface of the medium nor over the thickness of the medium.

A further characteristic of a coating layer according to the present invention is that the coating layer has substantially the same thickness over the whole free area surface.

With “substantially the same thickness” is meant that although there can be some small deviations in the thickness over the surface of the medium and over the thickness of the medium, there are no structural deviations neither over the surface of the medium nor over the thickness of the medium.

For a coating thickness of 10 nm, deviations in thickness are at the most 1 nm; for a coating thickness of 100 nm, deviations in thickness are at the most 10 nm and for a coating thickness of 1000 nm, deviations in thickness are at the most 100 nm.

Coating Layer

In principle any composition of coating layers can be considered. Preferred coating layers comprise oxides, nitrides, fluorides and metals.

As oxides Al₂O₃, TiO₂, SiO₂, ZrO₂, HfO₂, Ta₂O₅, NbO₅, Y₂O₃, MgO, CeO₂, La₂O₃, SrTiO₃, BaTiO₃, In₂O₃, SnO₂, ZnO, Ga₂O₃, NiO, YBa₂Cu₃O₇₋ₓ, LaCoO₃, LaNiO can be considered.

Examples of nitrides comprise AlN, GaN, InN, SiNx, TiN, TaN, Ta₃N₅, NbN and MoN.

Examples of fluorides comprise CaF₂, SrF₂ and ZnF₂.

Examples of metals comprise Si, Ge, Cu, Mo, Ti, W, Ni, Ag, Au, Pt and Pd.

The coating layer has preferably a stoechiometric composition.

Thickness of Coating Layer

In principle, any thickness of the coating layer can be obtained as the thickness of the coating layer can be controlled perfectly at an atomic scale by the deposition technique of ALD.

However, the thickness of the coating layer is preferably between 10 and 1000 nm and more preferably between 50 and 500 nm, as for example 100 or 200 nm.

A great advantage of the present invention is that coating layers having a minimal thickness can be obtained.

A further advantage of the invention is that even thin coating layers such as coating layers having a thickness lower than 50 nm such as 20 nm are closed layers.

According to a second aspect of the present invention the use of a coated porous metal medium as described before as filter medium is provided.

Depending on the coating type of the coated porous metal medium, the filter medium can be used for filtration at high temperature, for filtration of corrosive fluids or for aggressive chemicals.

The coating layer applied on the free area surface S of the porous medium is so thin that the filter characteristics of the non-coated medium such as the mean pore size, the porosity and the filter rating are maintained by applying the coating layer.

According to a third aspect of the present invention a method to manufacture a coated porous metal medium comprising metal particles is provided.

The method comprises the steps of

providing a porous metal medium comprising metal particles, said metal particles defining a free area surface S;

applying a coating layer by atomic layer deposition on said free area surface S in such a way that said coating layer is covering said free area surface S substantially completely, said coating layer being substantially conformal, being substantial uniform in composition and having substantially the same thickness over the whole free area surface.

### DESCRIPTION OF THE PREFERRED EMBODIMENTS OF THE INVENTION

In an embodiment of the present invention, a non-woven porous metal medium comprising stainless steel fibers (316L) having a diameter of 2 μm is coated by means of atomic layer deposition (ALD).

The uncoated non-woven porous metal medium has a porosity of 86%, a thickness of 500 μm.

The stainless steel fibers define a free area surface S of 150 m²/m² macroscopic surface of the non-woven porous metal medium.

Using ALD, the medium was conformally coated with a stoichiometric Al₂O₃ coating layer. The Al₂O₃ coating layer has a thickness of 80 nm.

After the application of the coating layer, the porosity of the coated medium remains the same as the porosity of the uncoated medium, i.e. 86%.

By means of SEM, it was verified that the free area surface S is completely coated with the coating layer, i.e. that all steel fibers are covered by the Al₂O₃ coating layer.

The coated porous metal medium described above is compared to an uncoated porous metal medium in an electrochemical corrosion analysis. The corrosion current is measured in an electrolyte. The used electrolyte comprises 0.1 N H₂SO₄ in 90% ethanol. This type of electrolyte is chosen in order to achieve an optimal wettability (contact angle of 0°)so that the corrosion behavior of the free area surface S of the porous medium can be measured.

The obtained corrosion current for the uncoated and the coated porous metal medium, expressed as μA/cm² of macroscopic porous medium is given in Table 1.

TABLE 1

| | Corrosion current |
|---|---|
| | (0.1N H₂SO₄ in 90% ethanol) |
| Sample | (μA/cm²) |
| Uncoated porous metal medium | 6.02 |
| Coated porous metal medium | 0.23 |

The data of Table 1 show that the resistance of the coated porous metal medium is more than 96% higher than the resistance of the uncoated porous metal medium.

Because the wettability of used electrolyte is considered to be 100%, from the date of Table 1, it can be concluded that the total free area surface S of the porous metal medium is substantially completely coated as the coverage is more than 96% of the total free area surface.

To further demonstrate the difference between a coated porous metal medium according to the present invention and an uncoated porous metal medium, the above mentioned coated and uncoated porous metal medium are subjected to a heat treatment (500° C. during 12 hours).

The weight of the media were determined before and after the heat treatment.

After the heat treatment the weight of the uncoated porous metal medium was increased with 1.4% whereas the weight of the coated porous metal medium according to the present invention showed only a small increase of 0.1%.

The above mentioned tests are thus illustrating that by using ALD, a substantially uniform and conformal thin coating layer can be deposited resulting in a greatly improved corrosion resistance.

As mentioned above, depending on the type of the coating layer that is deposited on the porous metal medium different functionalities can be given to the medium.

1-13. (canceled)

14. A method of manufacturing a porous metal medium that comprises:
(A) providing a porous metal medium that includes metal particles defining a free area surface S; and
(B) applying a coating layer on the free area surface S using atomic layer deposition such that the coating layer covers the free area surface S substantially completely and the coating layer is substantially conformal, substantially uniform in composition and substantially uniform in thickness over the free area surface.

15. The method according to claim 14, wherein the metal particles comprise metal powder and/or metal fibers.

16. The method according to claim 14, wherein the metal particles comprise steel particles.

17. The method according to claim 14, wherein the metal particles comprise stainless steel particles.

18. The method according to claim 14, wherein the metal particles comprise metal fibers having a diameter ranging between 1 and 100 μm.

19. The method according to claim 14, wherein the porous metal medium comprises a non-woven porous metal medium comprising sintered metal.

20. The method according to claim 14, wherein the porous metal medium comprises a sintered metal powder.

21. The method according to claim 14, wherein the coating layer comprises an oxide, a nitride, a fluoride or a metal.

22. The method according to claim 19, further comprising selecting the oxide from the group consisting of Al₂O₃, TiO₂, SiO₂, ZrO₂, HfO₂, Ta₂O₅, NbO₅, Y₂O₃, MgO, CeO₂, La₂O₃, SrTiO₃, BaTiO₃, In₂O₃, SnO₂, ZnO, Ga₂O₃, NiO, YBa₂Cu₃O₇₋ₓ, LaCoO₃, and LaNiO and applying the selected oxide as the coating layer.

23. The method according to claim 14, wherein the coating layer comprises a stoechiometric coating layer.

24. The method according to claim 14, wherein the coating layer is applied in a thickness ranging between 10 and 1000 nm.

25. The method according to claim 19, further comprising selecting the nitride from the group consisting of AlN, GaN, InN, SiNx, TiN, TaN, Ta₃N₅, NbN and MoN and applying the selected nitride as the coating layer.

26. The method according to claim 19, further comprising selecting the fluoride from the group consisting of CaF₂, SrF₂ and ZnF₂ and applying the selected fluoride as the coating layer.

27. The method according to claim 19, further comprising selecting the metal from the group consisting of Si, Ge, Cu, Mo, Ti, W, Ni, Ag, Au, Pt and Pd and applying the selected metal as the coating layer.

28. The method according to claim 14, further comprising configuring the porous metal medium as a filter.
